(19) United States
(12) Patent Application Publication
(10) Pub. No.: US 2011/0108797 A1
(43) Pub. Date: May 12, 2011

(54) SINGLE CHIP TYPE WHITE LED DEVICE

(76) Inventors: Chu-Shou Yang, Taoyuan County (TW); Chia-Sing Wu, Taipei City (TW); Wu-Ching Chou, Hsinchu City (TW); Mei-Tsao Chiang, Taoyuan County (TW); Chi-Neng Mo, Taoyuan County (TW); Chih-Wei Luo, Hsinchu City (TW); Liang-Kuei Huang, Taipei City (TW)

(21) Appl. No.: 12/628,165

(22) Filed: Nov. 30, 2009

(30) Foreign Application Priority Data
Nov. 6, 2009 (TW) 098137685

(51) Int. Cl. H01L 33/00

(52) U.S. Cl. 257/13; 257/E33.008

(57) ABSTRACT

A single chip type white light LED device includes a first semiconductor layer of a first doping type, a ZnMnSeTe (Zinc Manganese Selenium Tellurium) red light quantum well, a first barrier layer disposed on the ZnMnSeTe red light quantum well, a green light emitting layer including green light quantum dots disposed on the first barrier layer, a second barrier layer disposed on the green light emitting layer, a blue light emitting layer including blue light quantum dots disposed on the second barrier layer, a third barrier layer disposed on the blue light emitting layer, and a second semiconductor layer disposed on the third barrier layer.

### BACKGROUND OF THE INVENTION

1. Field of the Invention

The present invention relates to a white light emitting diode (LED) device, and more particularly, to a single chip type white LED device which utilizes a Zinc Manganese Selenium Tellurium (ZnMnSeTe) quantum well to provide a red light, and utilizes group II-VI elements as the materials of quantum dots to provide a green light and a blue light.

2. Description of the Prior Art

As LEDs have advantages of low power consumption, long lifetime, low driving voltage, and rapid response, LEDs are widely applied in traffic signs, illumination lamps as well as in indication lights of electronics and etc. In addition, as developments of white LEDs rapidly grow, applications of the LEDs are further expanded to daily illumination lamps and backlights of liquid crystal display (LCD) devices.

Current white LEDs are mainly classified into two types, a first type white LED and a second type white LED. The first type white LED utilizes a blue LED with a fluorescent layer. The blue LED emits a blue light to excite the fluorescent layer so that the fluorescent layer could generate a yellow light which compensates with the blue light. Then the blue light and the yellow light are mixed through a lens to become a white light. Although the first type white LED has an advantage of low manufacturing cost, its white light is mixed though the blue light and the yellow light, lacking the content of a red light, resulting in poor color purity. Furthermore, the wavelength range of the blue light and the yellow light must be accurate; otherwise a color shift could result to the mixed white light due to a poor compensation. Moreover, the installation of the fluorescent layer and the lens structures results in an increase in size of the first type white LED. The second type white LED packages a red LED chip, a green LED chip and a blue LED chip of three different colors into the white LED. The packaged white LED mixes the red light emitted by the red LED, the green light emitted by the green LED, and the blue light emitted by the blue LED to form the white light. However, the LED with three chips requires additional driving circuits to drive the red LED, the green LED, and the blue LED respectively, thereby increasing the manufacturing cost and manufacturing complexity.

### SUMMARY OF THE INVENTION

It is one of the objectives of the present invention to provide a single chip type white LED device for reducing the manufacturing cost and increasing the color purity.

In accordance to an embodiment of the present invention, a single chip type white LED device is provided. The single chip type white LED device includes a first semiconductor layer having a first doping type, a ZnMnSeTe red light quantum well disposed on the first semiconductor layer, a first barrier layer disposed on the ZnMnSeTe red light quantum well, a green light emitting layer including a plurality of green light quantum dots disposed on the first barrier layer, a second barrier layer disposed on the green light emitting layer, a blue light emitting layer including a plurality of blue light quantum dots disposed on the second barrier layer, a third barrier layer disposed on the blue light emitting layer, and a second semiconductor layer having a second doping type disposed on the third barrier layer.

The single chip type white LED device in accordance to the present invention utilizes the ZnMnSeTe quantum well as a red light emitting layer, and utilizes group II-VI elements as materials of the green light emitting layer and the blue light emitting layer. The materials mentioned above have similar lattices. The similar lattices reduce the formation of dislocations and raise the light-emitting efficiency of the materials mentioned above. In addition, the green light emitting layer and the blue light emitting layer exist in the form of quantum dots, which further prevents the light-emitting efficiency from being affected by the dislocations. Moreover, the single chip type white LED device in accordance to the present invention mixes the red light, the green light, and the blue light to form the white light. Mixing of the three lights prevents the problem of color shift which is often observed in conventional LEDs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a single chip type white LED device in accordance to a preferred embodiment of the present invention.

FIG. 2 is a schematic diagram illustrating energy level variation of electrons in the ZnMnSeTe red light quantum well in accordance to the present embodiment.

FIG. 3 is a schematic diagram illustrating light-emitting intensities and wavelengths of the green light quantum dots and wavelengths of the blue light quantum dots in accordance to the present embodiment.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”.

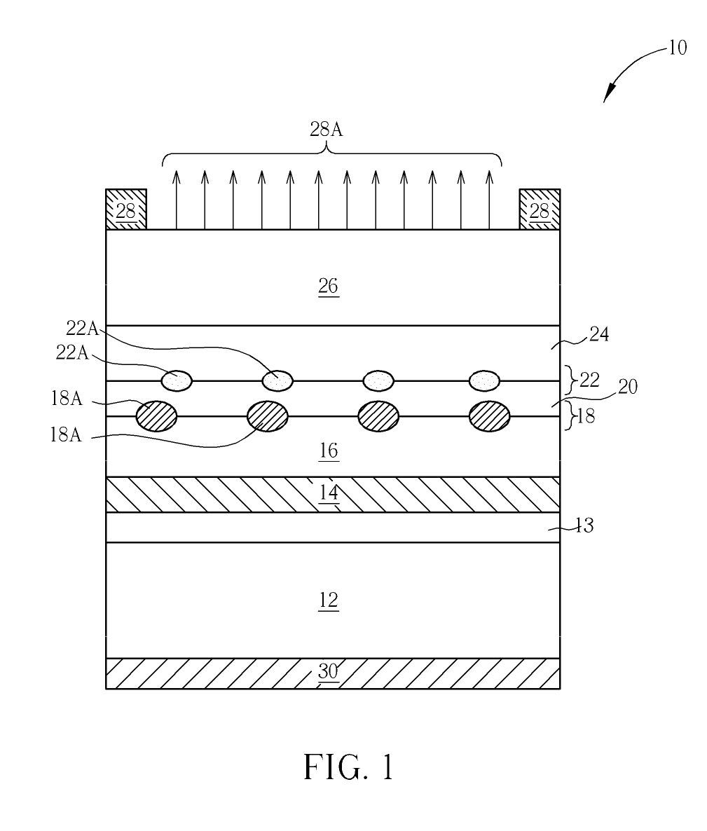

Referring to FIG. 1, FIG. 1 is a schematic diagram of a single chip type white LED device in accordance to a preferred embodiment of the present invention. As illustrated in FIG. 1, the single chip type white LED device 10 in accordance to the present embodiment includes a first semiconductor layer 12, a ZnMnSeTe red light quantum well 14 disposed on the first semiconductor layer 12, a first barrier layer 16 disposed on the ZnMnSeTe red light quantum well 14, a green light emitting layer 18 disposed on the first barrier layer 16, a second barrier layer 20 disposed on the green light emitting layer 18, a blue light emitting layer 22 disposed on the second barrier layer 20, a third barrier layer 24 disposed on the blue light emitting layer 22, and a second semiconductor layer 26 disposed on the third barrier layer 24. In addition, a buffer layer 13 may be disposed between the first semiconductor layer 12 and the ZnMnSeTe red light quantum well 14.

The first semiconductor layer 12 has a first doping type, such as a P doping type. In accordance with the present embodiment, a zinc doped GaAs substrate may be selected as the first semiconductor layer 12, but is not limited. The ZnMnSeTe red light quantum well 14 is used to provide a source of red light. The purpose of the buffer layer 13 is to enhance the lattice match between the first semiconductor layer 12 and the ZnMnSeTe red light quantum well 14, and a band gap of the buffer layer 13 must be higher than a band gap of the ZnMnSeTe red light quantum well 14, to restrict the carriers inside the ZnMnSeTe red light quantum well 14. Therefore, material selections of the buffer layer 13 must satisfy the two conditions above. In accordance with the present embodiment, an un-doped ZnSe layer is selected as the material of the buffer layer 13, but is not limited. Other materials which satisfy the two conditions mentioned above may also be selected as the materials for the buffer layer 13. The green light emitting layer 18 which acts as a source of the green light includes a plurality of green light quantum dots 18A. The blue light emitting layer 22 which acts as a source of the blue light includes a plurality of blue light quantum dots 22A.

The first barrier layer 16, the second barrier layer 20 and the third barrier layer 24 serve a purpose of restricting electrons within the ZnMnSeTe red light quantum well 14 for reactions, restricting electrons within the green light emitting layer 18 or the blue light emitting layer 22 for reactions. Therefore, during the materials selection, a selected material for the first barrier layer 16, the second barrier layer 20 and the third barrier layer 24 must have a higher band gap than the band gap of the ZnMnSeTe red light quantum well 14, the band gap of the green light emitting layer 18, and the band gap of the blue light emitting layer 22. In addition, crystal lattices of the first barrier layer 16, the second barrier layer 20, and the third barrier layer 24 must also match with crystal lattices of the ZnMnSeTe red light quantum well 14, the crystal lattices of the green light emitting layer 18 or the blue light emitting layer 22, in order to avoid dislocations induced by lattice mismatches. The dislocations induced by lattice mismatches affect the light-emitting efficiency as well as the service life of the device. Base on the above considerations, materials of the first barrier layer 16, the second barrier layer 20 and the third barrier layer 24 should match with the materials of the ZnMnSeTe red light quantum well 14, the green light emitting layer 18 and the blue light emitting layer 22. In accordance to the present embodiment, ZnSe is selected as the material of the first barrier layer 16, the second barrier layer 20, and the third barrier layer 24, but is not limited. Other appropriate materials in group II-VI may also be selected.

The second semiconductor layer 26 has a second doping type such as an N doping type. In accordance to the present embodiment, chlorine doped ZnSe is selected as the material of the second semiconductor layer 26, but is not limited. Furthermore, in order to provide a forward bias voltage, an electrode 28 e.g. a platinum chromium alloy electrode is disposed on the surface of the second semiconductor layer 26 which is opposite to the surface of the second semiconductor layer 26 facing the third barrier layer 24. The electrode 28 has a light-pervious region 28A and the light-pervious region 28A allows the white light emitted by the single chip type white LED device 10 to exit. On the other hand, an electrode 30 e.g. an indium electrode is disposed on the surface of the first semiconductor layer 12 which is opposite to the surface of the first semiconductor layer 12 facing the buffer layer 13, but is not limited.

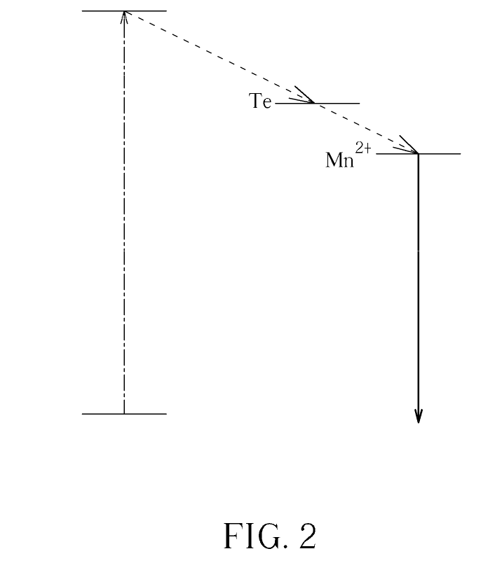

The passage below describes the light-emitting theorems of the ZnMnSeTe red light quantum well 14, the green light quantum dots 18A, and the blue light quantum dots 22A of the present invention. Referring to FIG. 2 and FIG. 1 together, FIG. 2 is a schematic diagram illustrating energy level variation of electrons in the ZnMnSeTe red light quantum well 14 in accordance to the present embodiment. As illustrated in FIG. 2, under the driving of the forward bias voltage, electrons within the second semiconductor layer 26 are excited to a conductive band as illustrate by the dash-dot line of FIG. 2. In accordance to the present embodiment, a ZnMnSeTe alloy is selected as the material of the ZnMnSeTe red light quantum well 14. Te content of the ZnMnSeTe alloy has a high carrier capture efficiency which can act as a medium of carrier mobility. Under such circumstances, electrons at the conduction band are first captured by Te, and then the electrons rapidly migrate to the Mn²⁺ band gap, as illustrated by the dash line of FIG. 2. Since the electrons under the band gap of Mn²⁺ ions are in an unstable excitement state, the electrons have a tendency to drop to a stable state, as illustrated by the solid line of FIG. 2, and the red light is emitted during such process. In accordance to the present embodiment, the Mn²⁺ ion in the ZnMnSeTe red light quantum well 14 has a band gap of about 2.0 electron volts (eV), thereby releasing the red light with a wavelength of about 620 nanometers (nm). It is to be noted that, in accordance to the present embodiment, the Mn and Te contents in the ZnMnSeTe red light quantum well 14 are fairly low. For example, the atomic percentage of Mn in the ZnMnSeTe red light quantum well 14 is substantially between 2% and 5% and a preferred Mn atomic percentage in the ZnMnSeTe red light quantum well 14 is 3%. Furthermore, the atomic percentage of Te in the ZnMnSeTe red light quantum well 14 is substantially between 3% and 7%, and a preferred Te atomic percentage in the ZnMnSeTe red light quantum well 14 is 5%. As described in the previous passage, Te exhibits high carrier capture efficiency and with the presence of Te, only a minor amount of Mn is required to achieve a high light-emitting efficiency. In addition, although the concentrations of Mn and Te are fairly low, the low Mn and Te contents are sufficient to adjust the band gap so that the band gap of the ZnMnSeTe red light quantum well 14 (about 2.75 eV) is smaller than that of the band gap of the buffer layer 13 (about 2.8 eV) made of ZnSe and that of the first barrier layer 16 (about 2.8 eV) made of ZnSe. Therefore, a quantum confinement effect is ensured. Furthermore, the minor amounts of Mn and Te ions possess almost no effect on the crystal lattice of the ZnMnSeTe red light quantum well 14 so that the lattice parameters of the ZnMnSeTe red light quantum well 14 is similar to the lattice parameters of the first semiconductor layer 12 (e.g. made of ZnSe) and the first barrier layer 16 (e.g. made of ZnSe). The similar lattice parameters avoid the formation of dislocations. Moreover, in accordance to the present embodiment, a thickness of the ZnMnSeTe red light quantum well 14 (well width) is substantially between 1 nm and 5 nm, and a preferred thickness of the ZnMnSeTe red light quantum well 14 is 2 nm. The range of well width described above has not yet reached the lattice relation of the ZnMnSeTe red light quantum well 14 and thereby the formation of dislocations can be reduced.

Again referring to FIG. 1, the green light quantum dots 18A and the blue light quantum dots 22A in accordance to the present embodiment provide a green light source and a blue light source respectively. Since the green light quantum dots 18A and the blue light quantum dots 22A are dispersed in the form of quantum dots, the green light quantum dots 18A and the blue light quantum dots 22A are unlikely to be affected by the dislocations. In other words, only a minor amount of the green light quantum dots 18A and a minor amount of the blue light quantum dots 22A would be affected by the dislocations. A mass majority of the green light quantum dots 18A and a mass majority of the blue light quantum dots 22A can still emit light normally. In accordance to the present embodiment, a thickness of the green light emitting layer 18 is substantially between 2.5 and 3 atomic layers, and a preferred thickness of the green light emitting layer 18 is 2.5 atomic layers. Also, a density of the green light quantum dots 18A is substantially between 5*10⁸ cm⁻² and 1*10⁹ cm⁻², and a preferred density of the green light quantum dots 18A is 1*10⁹ cm⁻², but is not limited. In addition, a thickness of the blue light emitting layer 22 is substantially between 1.5 and 2.5 atomic layers, and a preferred thickness of the blue light emitting layer 22 is 1.5 atomic layers. Also, a density of the blue light quantum dots 22A is substantially between 5*10⁸ cm⁻² and 1*10⁹ cm⁻², and a preferred density of the blue light quantum dots 22A is 1*10⁹ cm⁻², but is not limited. Furthermore, in accordance to the present embodiment, the same group II-VI elements are selected as the materials of the green light quantum dots 18A and the blue light quantum dots 22A. The group II-VI elements have similar band gaps, but the size of the blue light quantum dots 22A is smaller than the size of the green light quantum dots 18A. Thus, under a quantum confinement effect, the green light quantum dots 18A with a larger size emit the green light, and the blue light quantum dots 22A with a smaller size emit the blue light. For instance, the green light quantum dots 18A can be green light CdSe quantum dots with a band gap of 1.7 eV, and the blue light quantum dots 22A can be blue light CdSe quantum dots with a band gap of 1.7 eV, or the green light quantum dots 18A can be green light ZnTe quantum dots and the blue light quantum dots 22A can be blue light ZnTe quantum dots. The materials of the green light quantum dots 18A and the blue light quantum dots 22A are not limited to the materials mentioned above, and other appropriate group II-VI elements may also be the materials of the green light quantum dots 18A and the blue light quantum dots 22A.

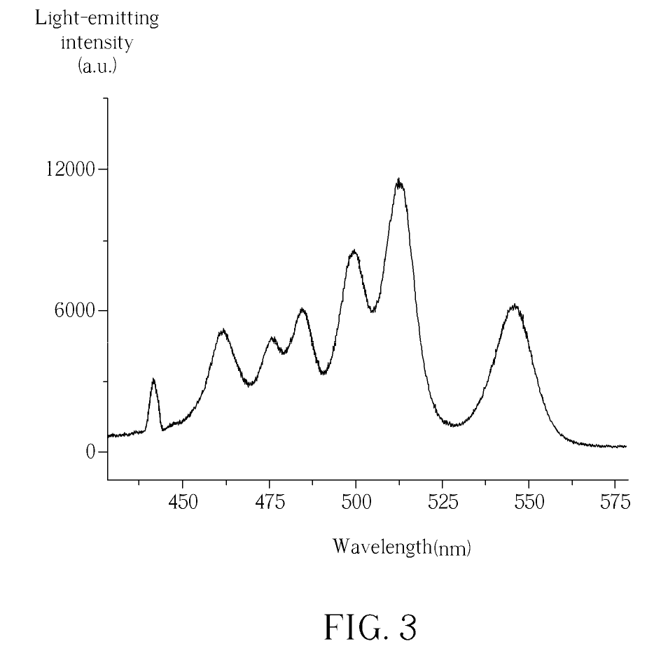

Referring to FIG. 3 and FIG. 1 at a same time, FIG. 3 is a schematic diagram illustrating light-emitting intensities and wavelengths of the green light quantum dots and wavelengths of the blue light quantum dots in accordance to the present embodiment. As illustrated in FIG. 3, the green light quantum dots 18A in accordance to the present embodiment emit green light in a range of wavelength between 510 nm and 550 nm with an intensity reaching 6000 to 12000 arbitrary units (a.u.). The blue light quantum dots 22A in accordance to the present embodiment emit blue light in a range of wavelength between 460 nm and 500 nm with an intensity reaching 3000 to 6000 a.u.

In summary, the single chip type white LED device in accordance to the present invention uses a ZnMnSeTe quantum well as the red light emitting layer, and the single chip type white LED device uses group II-VI elements as the materials to fabricate the green light emitting layer and the blue light emitting layer. The above mentioned materials have similar lattice parameters which reduce the formation of dislocations and raise the light-emitting efficiency. Furthermore, the green light emitting layer and the blue light emitting layer are present in the form of quantum dots, and thereby further prevent the dislocations from affecting the light emitting efficiency. Moreover, the single chip type white LED device in accordance to the present invention mixes the red light, the green light and the blue light to form the white light which avoids the problem of color shift as seen in conventional white LEDs.

Those skilled in the art will readily observe that numerous modifications and alterations of the device and method may be made while retaining the teachings of the invention.

What is claimed is:

1. A single chip type white LED device, comprising:
a first semiconductor layer having a first doping type;
a ZnMnSeTe red light quantum well disposed on the first semiconductor layer;
a first barrier layer disposed on the ZnMnSeTe red light quantum well;
a green light emitting layer disposed on the first barrier layer, wherein the green light emitting layer comprises a plurality of green light quantum dots;
a second barrier layer disposed on the green light emitting layer;
a blue light emitting layer disposed on the second barrier layer, wherein the blue light emitting layer comprises a plurality of blue light quantum dots;
a third barrier layer disposed on the blue light emitting layer; and
a second semiconductor layer disposed on the third barrier layer, wherein the second semiconductor layer has a second doping type.

2. The single chip type white LED device of claim 1, wherein the ZnMnSeTe red light quantum well has a manganese atomic percentage substantially between 2% and 5%.

3. The single chip type white LED device of claim 1, wherein the ZnMnSeTe red light quantum well has a tellurium atomic percentage substantially between 3% and 7%.

4. The single chip type white LED device of claim 1, wherein a thickness of the ZnMnSeTe red light quantum well is substantially between 1 nanometers and 5 nanometers.

5. The single chip type white LED device of claim 1, wherein the green light quantum dots and the blue light quantum dots are made of a same material, and a size of the blue light quantum dots is smaller than a size of the green light quantum dots.

6. The single chip type white LED device of claim 5, wherein the green light quantum dots comprise green light CdSe quantum dots, and the blue light quantum dots comprise blue light CdSe quantum dots.

7. The single chip type white LED device of claim 5, wherein the green light quantum dots comprise green light ZnTe quantum dots, and the blue light quantum dots comprise blue light ZnTe quantum dots.

8. The single chip type white LED device of claim 1, wherein a thickness of the green light emitting layer is substantially between 2.5 and 3 atomic layers.

9. The single chip type white LED device of claim 1, wherein a density of the green light quantum dots of the green light emitting layer is substantially between 5*10⁸ cm⁻² and 1*10⁹ cm⁻².

10. The single chip type white LED device of claim 1, wherein a thickness of the blue light emitting layer is substantially between 1.5 and 2.5 atomic layers.

11. The single chip type white LED device of claim 1, wherein a density of the blue light quantum dots of the blue light emitting layer is substantially between 5*10⁸ cm⁻² and 1*10⁹ cm⁻².

12. The single chip type white LED device of claim 1, wherein the first semiconductor layer is a p doping type semiconductor layer, and the second semiconductor layer is an n doping type semiconductor layer.

13. The single chip type white LED device of claim 1, wherein the first barrier layer comprises a ZnSe layer, the second barrier layer comprises a ZnSe layer, and the third barrier layer comprises a ZnSe layer.

14. The single chip type white LED device of claim 1 further comprising a buffer layer disposed between the first semiconductor layer and the ZnMnSeTe red light quantum well.

15. The single chip type white LED device of claim 14, wherein the buffer layer comprises an un-doped ZnSe layer.
